(19) United States
(12) Patent Application Publication
(10) Pub. No.: US 2005/0012184 A1
(43) Pub. Date: Jan. 20, 2005

(54) Semiconductor packaging structure

(76) Inventors: Chen-Jung Tsai, Hsinchu (TW); Chih-Wen Lin, Hsinchu (TW)

Correspondence Address: BIRCH STEWART KOLASCH & BIRCH, PO BOX 747, FALLS CHURCH, VA, 22040-0747, US

(21) Appl. No.: 10/755,469

(22) Filed: Jan. 13, 2004

(30) Foreign Application Priority Data
Jul. 17, 2003 (TW) 092119501

(51) Int. Cl. H01L 23/495

(52) U.S. Cl. 257/666

(57) ABSTRACT

A semiconductor packaging structure. The structure comprises a chip, a lead frame, and a plurality of wires. The chip comprises an active surface and an opposing non-active surface, the active surface comprising a central area and a peripheral area having a plurality of bonding pads. The lead frame comprises a plurality of the leads, a plurality of tie bars, and a chip paddle. The tie bars is connected with the chip paddle and attached to the active surface of the chip in such a way as to avoid contact with the bonding pads. As well, the wires electrically connect with the bonding pad and the leads.

### BACKGROUND OF THE INVENTION

1. Field of the Invention

The present invention relates to a semiconductor packaging structure and in particular to a thin semiconductor packaging structure.

2. Description of the Related Art

In recent years, packaging has become a performance-limiting factor for microelectronic devices, with size, weight, cost, pin count, and power consumption assuming importance in packaging design. Packaging design must generally trade off between material, structure, and electronic property considerations to obtain a cost-effective and reliable design. Conventionally, as shown in FIG. 1, a chip 1 is usually attached to a chip paddle 2 of a lead frame by epoxy or other adhesive. Wires 5 connect with bonding pads 3 deposited on the chip and the leads 4. The resulting structure is then encapsulated by a molding compound 6, thus completing the package.

However, the thickness of the semiconductor packaging structure mentioned, including thickness of chip 1, thickness of chip paddle 2, loop height of the wires 5, and even the encapsulation 6, is too thick to satisfy the new generation of small and thin electric products.

### SUMMARY OF THE INVENTION

Accordingly, an object of the invention is to provide a semiconductor packaging structure with reduced thickness.

It is another object of the invention to provide a semiconductor packaging structure with enhanced heat dissipation.

To achieve the above objects, the present invention provides a lead frame having a plurality of tie bars and chip paddle, resulting in the compatibilities of a plurality of bonding pads of a chip with the tie bars and chip paddle of the lead frame when an active surface of the chip adheres to a first adhering surface of the chip paddle of the lead frame using non-conductive solid or liquid glue. The present invention also allows encapsulation formed by molding, dispensing, or stencil printing, depending on packaging types, and exposing an opposing non-active surface of the chip and/or the chip paddle in order to satisfy the requirement of heat dissipation and minimization of assembly thickness. Further, the design of leads of the lead frame can differ as the packaging type differs for the subsequent process.

The present invention provides a semiconductor packaging structure comprising a chip, a designed lead frame, and a plurality of wires. The chip comprises an active surface and an opposing non-active surface, the active surface consists of a central area and a peripheral area having a plurality of bonding pads. The designed lead frame comprises a plurality of the leads, a plurality of tie bars, and a chip paddle. The tie bars connect with the chip paddle and adhere to the active surface of the chip in such a way as to avoid contact with the bonding pads. As well, the wires electrically connect with the bonding pad and the leads.

The semiconductor packaging structure of the present invention further comprises an encapsulation covering the active surface of the chip, the bonding pads, the adhering surface of the chip paddle, and the wire-connecting surface of the lead, and the wires.

The arrangement of the encapsulation can be modified in several ways.

In one modification, the encapsulation covers the bonding pads, leads, wires, chip paddle, and the active surface of the chip, exposing the opposing non-active surface of the chip.

In one of the other modifications, the encapsulation covers the bonding pads, leads, wires, the active surface of the chip, and the adhering surface of the chip paddle, exposing the opposing non-active surface of the chip and an opposing non-adhering surface of the chip paddle.

In the present invention, each lead further comprises an inner lead covered by the encapsulation and outer lead extending beyond the encapsulation.

In the present invention, the chip paddle is adhered to the active surface of the chip using non-conductive solid or liquid glue. Further, the loop height of the wires can be controlled to be lower than the thickness of the chip paddle. The wires can be metal.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a cross-section of a conventional semiconductor packaging structure;

FIG. 2 is a cross-section of a semiconductor packaging structure according to the first embodiment of the invention;

FIG. 3 is a top view of the semiconductor packaging structure according to FIG. 2;

FIG. 4 is a cross-section of a semiconductor packaging structure according to the second embodiment of the invention, wherein the structure comprises an encapsulation;

FIGS. 5A through 5B are cross-sections of a semiconductor packaging structure according to the third embodiment of the invention, wherein the non-active surface of the chip, and the wire non-connecting surface of the leads are exposed, and the wire-connecting surface of leads can be entirely covered by the encapsulation, as shown in FIG. 5A, or a plurality of outer leads extend beyond the encapsulation, as shown in FIG. 5B;

FIGS. 6A through 6B are cross-sections of a semiconductor packaging structure according to the fourth embodiment of the invention, wherein the non-active surface of the chip, the wire non-connecting surface of the leads and the non-adhering surface of the chip paddle are exposed, and the wire-connecting surface of leads can be entirely covered by the encapsulation, as shown in FIG. 6, or a plurality of outer leads extend beyond the encapsulation, as shown in FIG. 6B.

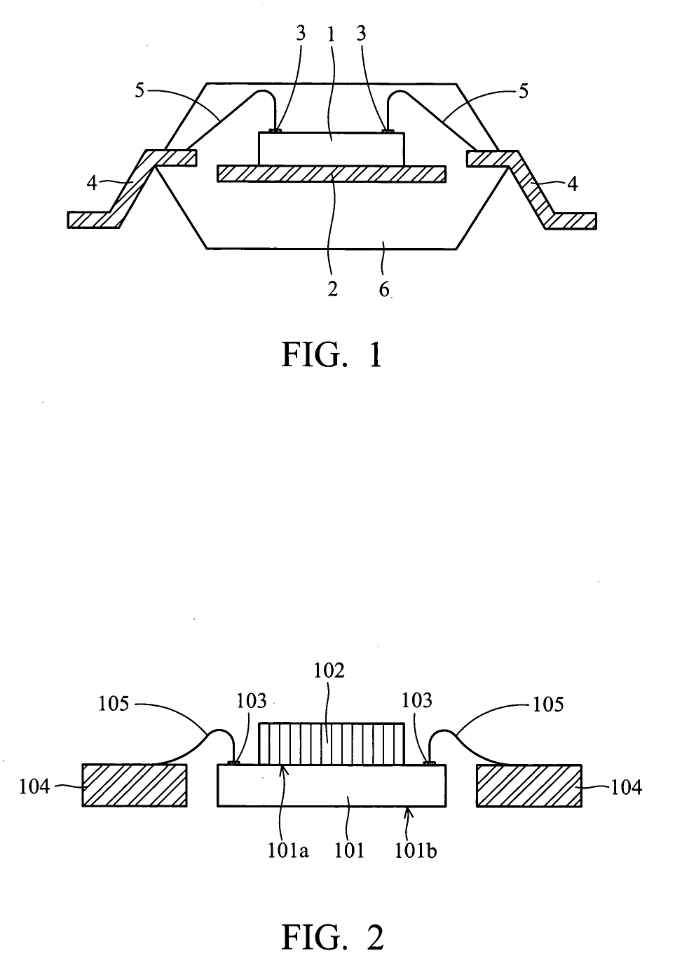

### DETAILED DESCRIPTION OF THE INVENTION

The present invention is now described with reference to the figures.

First Embodiment

In FIG. 2, a semiconductor packaging structure according to the present invention is shown. Number 101 indicates a chip comprising an active surface 101a and an opposing non-active surface 101b, wherein the active surface 101a consists of a central area and a peripheral area. A plurality of bonding pads 103 are arranged on the peripheral area of the chip 101.

A chip paddle 102 is connected with the central area of the chip 101 by non-conductive solid or liquid glue. The surface area of the chip paddle 102 is smaller than that of the active surface 101a of the chip 101, thus the chip paddle 102 can be arranged to connect with the active surface 101a of the chip 100 without covering the bonding pad 103.

A plurality of the leads 104 respectively corresponding to bonding pads 103 are arranged beside the chip 101. As well, a plurality of electric conductivity wires 105, electrically connects the bonding pad 103 and the leads 104. The loop height of the wires 105 are lower than the top surface of the chip paddle 102, such that the total thickness of the semiconductor packaging structure is reduced.

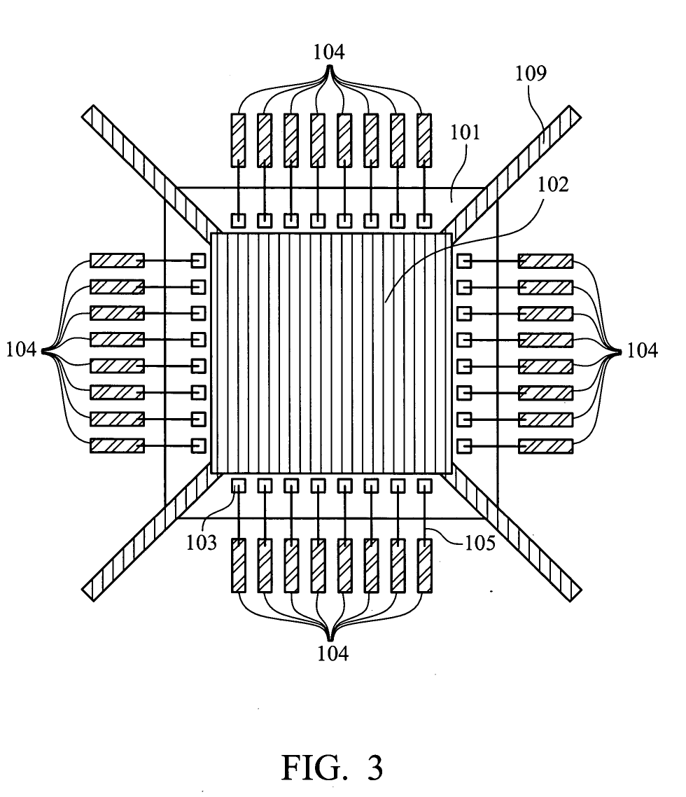

FIG. 3 is a top view of the semiconductor packaging structure of FIG. 2. A lead frame comprises the leads 104, a plurality of tie bars 109, and the chip paddle 102. The tie bars 109 connect to the chip paddle 102 and adhere to the active surface 101a of the chip 101 in such a way as to avoid contact with the bonding pads 103.

Second Embodiment

The semiconductor packaging structure of the present invention as described above can further be covered by an encapsulation to prevent machine or moisture damage.

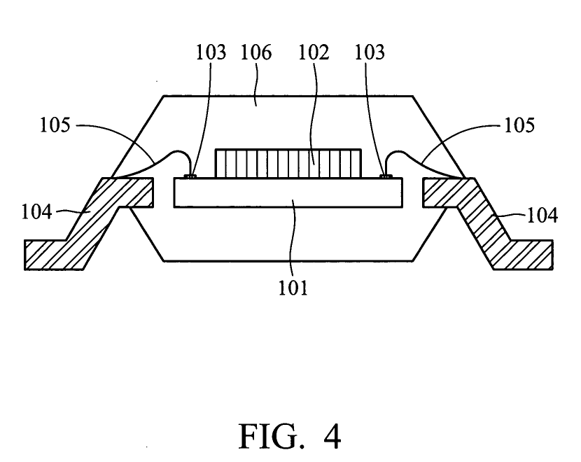

In FIG. 4, an encapsulation 106 is disposed covering several elements of the semiconductor packaging structure as described in first embodiment, which, for brevity, is not illustrated again here. In the present embodiment, the chip 101, the chip paddle 102, the bonding pad 103, the wires 105, and parts of the leads are covered by the encapsulation 106. The parts of the leads covered by the encapsulation 106 are defined as inner leads, and those extending beyond the encapsulation 106 as outer leads.

Third Embodiment

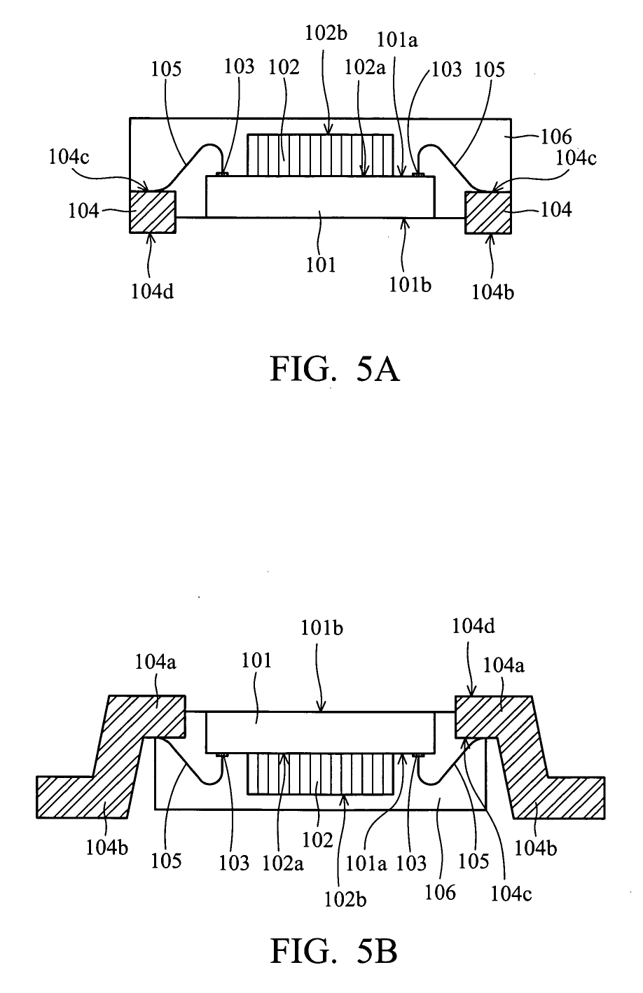

In FIGS. 5A and 5B, the encapsulation 106 covers the semiconductor packaging structure as described in a different configuration in the first embodiment, and which, for brevity, is not illustrated again here. The leads 104 comprise two surfaces, one, a wire-connecting surface 104c connecting with the wires 105, and another, a wire non-connecting surface 104d, not connecting.

In this embodiment, the non-active surface 101b of the chip 101 and the wire non-connecting surface 104d are exposed beyond the encapsulation 106, which covers only the active surface of the chip 101a, the chip paddle 102, the bonding pad 103, and the wire-connecting surface 104c. Beneficial improvement of heat dissipation is thus provided.

The parts of the leads 104 covered by the encapsulation 106 are defined as inner leads 104a, and those extending beyond the encapsulation 106 are defined as outer leads 104b. The leads 104 can be completely covered by the encapsulation 106, as shown in FIG. 5A and also comprise the inner leads 104a covered by the encapsulation 106 and the outer leads 104b extending beyond the encapsulation 106, as shown in FIG. 5B. The outer leads 104b benefit second level packaging.

Fourth Embodiment

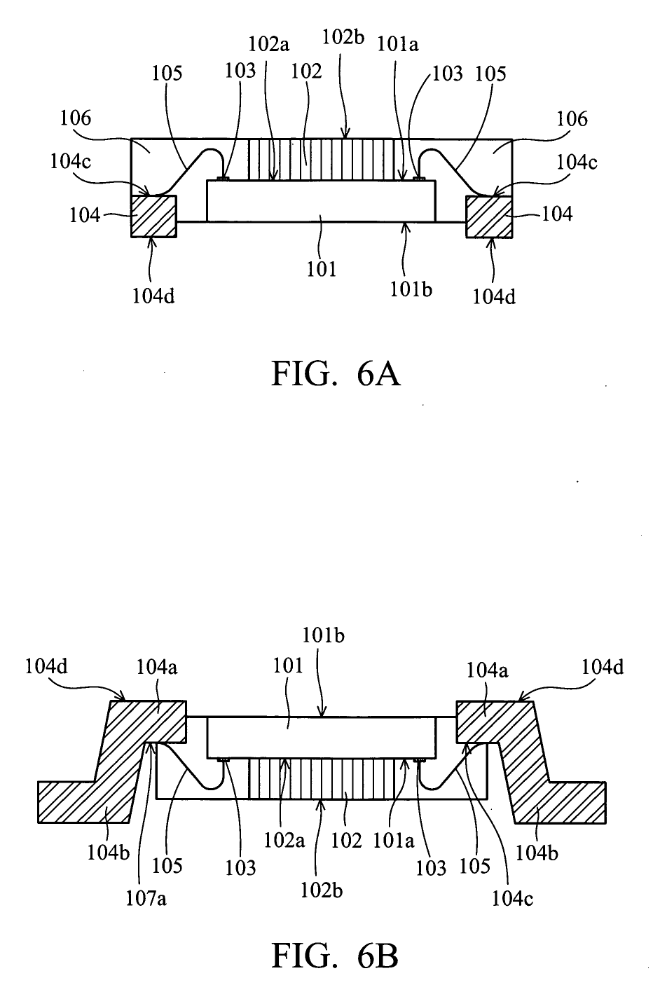

In FIGS. 6A and 6B, the encapsulation 106 covers the semiconductor packaging structure as described in a different configuration in the first embodiment, and which, for brevity, is not illustrated again here. The surface of the chip paddle 102 connected with the chip 100 is further defined as an adhering surface 102a connecting with the chip 101, and the opposite surface as a non-adhering surface 102b.

In this embodiment, the non-active surface 101b of the chip 101, the non-adhering surface 102b, and the wire non-connecting surface 104d of the leads 104 are exposed beyond the encapsulation 106. The encapsulation 106 covers only the active surface of the chip 101a, the chip paddle 102, the bonding pad 103, and the wire-connecting surface 104c of the leads 104. Beneficial improvement of heat dissipation is thus provided.

The parts of the leads covered by the encapsulation 106 are defined as inner leads 104a, and those extending beyond the encapsulation 106 are defined as outer leads 104b. The leads 104 can be completely covered by the encapsulation 106, as shown in FIG. 5A, and can also comprise the inner leads 104a covered by the encapsulation 106 and the outer leads 104b extending beyond the encapsulation 106, as shown in FIG. 5B. The outer leads 104b benefit second level packaging.

Accordingly, the present invention provides several advantages. First, the back of the chip (non-active surface) and/or the chip paddle (non-adhering surface) can extend beyond the encapsulation to increase heat-dissipation area, enhancing reliability of the chip. Second, the total thickness of the semiconductor packaging structure is significantly reduced.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation to encompass all such modifications and similar arrangements.

1. A semiconductor packaging structure, comprising:
a chip having an active surface and an opposing non-active surface, wherein the active surface consists of a central area and a peripheral area having a plurality of bonding pads;
a lead frame comprising a plurality of the leads, a plurality of tie bars, and a chip paddle, the tie bars connecting to the chip paddle and attached to the active surface of the chip in such a way as to avoid contact with the bonding pads; and
a plurality of wires electrically connecting the bonding pad and the leads.

2. The structure as claimed in claim 1, further comprising an encapsulation covering the chip, the bonding pads, the chip paddle, the leads, and the wires.

3. The structure as claimed in claim 1, wherein the chip paddle and the active surface of the chip are connected by non-conductive solid or liquid glue.

4. A semiconductor packaging structure, comprising:
a chip having an active surface and an opposing non-active surface, wherein the active surface consists of a central area and a peripheral area having a plurality of bonding pads;
a lead frame comprising a plurality of the leads, a plurality of tie bars, and a chip paddle, the tie bars connecting to the chip paddle and attached to the active surface of the chip in such a way as to avoid contact with the bonding pads, and each of the leads comprising a wire-connecting surface and a wire non-connecting surface;
a plurality of wires electrically connecting with the bonding pad and the wire-connecting surface of the leads; and
an encapsulation covering the active surface of the chip, the bonding pads, the chip paddle, the wire-connecting surface of the leads, and the wires, such that the opposing non-active surface of the chip and the wire non-connecting surface of the leads are thereby exposed.

5. The structure as claimed in claim 4, wherein the leads further comprise a plurality of inner leads and outer leads covered by the encapsulation and outer leads extending beyond the encapsulation.

6. The structure as claimed in claim 4, wherein the chip paddle and the active surface of the chip are connected by non-conductive solid or liquid glue.

7. A semiconductor packaging structure, comprising:
a chip having an active surface and an opposing non-active surface, wherein the active surface consists of a central area and a peripheral area having a plurality of bonding pads;
a lead frame comprising a plurality of the leads, a plurality of tie bars, and a chip paddle having an adhering surface and a opposing non-adhering surface, the adhering surface is connected with the central area, the tie bars connecting to the chip paddle and attached to the active surface of the chip in such a way as to avoid contact with the bonding pads, and each of the leads comprising a wire-connecting surface and a wire non-connecting surface;
a plurality of wires electrically connecting with the bonding pad and the wire-connecting surface of the leads; and
an encapsulation covering the active surface of the chip, the bonding pads, the adhering surface of the chip paddle, and the wire-connecting surface of the lead, and the wires, such that the opposing non-active surface of the chip, the opposing non-adhering surface of the chip paddle and the wire non-connecting surface of the lead thereby exposed.

8. The structure as claimed in claim 7, wherein the leads further comprise a plurality of inner leads covered by the encapsulation and outer leads extending beyond the encapsulation.

9. The structure as claimed in claim 7, wherein the chip paddle and the active surface of the chip are connected by non-conductive solid or liquid glue.
